(19) United States
(12) Patent Application Publication
(10) Pub. No.: US 2014/0145783 A1
(43) Pub. Date: May 29, 2014

(54) SEMICONDUCTOR INTEGRATED CIRCUIT

(71) Applicants: Tomomitsu OHARA, Tokyo (JP); Masato YOSHIKUNI, Tokyo (JP)

(72) Inventors: Tomomitsu OHARA, Tokyo (JP); Masato YOSHIKUNI, Tokyo (JP)

(73) Assignee: MITSUMI ELECTRIC CO., LTD., Tokyo (JP)

(21) Appl. No.: 14/072,943

(22) Filed: Nov. 6, 2013

(30) Foreign Application Priority Data
Nov. 27, 2012 (JP) 2012-258451

(51) Int. Cl. H03K 17/687

(52) U.S. Cl. CPC H03K 17/687
USPC 327/434

(57) ABSTRACT

A semiconductor integrated circuit includes an output MOS transistor and a back gate control circuit. The output MOS transistor includes a first electrode connected to a power supply terminal and a second electrode connected to an output terminal. The output MOS transistor is configured to turn on and off to cause communications to be performed with another semiconductor integrated circuit connected to the output terminal. The back gate control circuit is configured to control an electric potential at a back gate of the output MOS transistor so that a current path between the power supply terminal and the output terminal at a time when a power supply connected to the power supply terminal is turned off is interrupted.

### CROSS-REFERENCE TO RELATED APPLICATION

This application is based upon and claims the benefit of priority of Japanese Patent Application No. 2012-258451, filed on Nov. 27, 2012, the entire contents of which are incorporated herein by reference.

### BACKGROUND OF THE INVENTION

1. Field of the Invention

The present invention relates to semiconductor integrated circuits capable of communicating with other semiconductor integrated circuits.

2. Description of the Related Art

FIG. 1 is a diagram illustrating a configuration of a communication system 100 according to related art. The communication system 100 is a communication circuit that includes multiple semiconductor integrated circuits IC1, IC2 and IC 3, which are interconnected via differential transmission lines LA and LB. The semiconductor integrated circuits IC1, IC2 and IC3 include respective communication interface circuits, which are equal to one another, and communicate with one another through differential signals transmitted on the transmission lines LA and LB. The respective communication interface circuits of the semiconductor integrated circuits IC1, IC2 and IC3 each include a receiver circuit A1, a transmission control circuit A2, and output MOS transistors M1, M2, M3 and M4.

The receiver circuit A1 outputs, from a terminal OUT, a reception signal corresponding to differential signals received from the transmission lines LA and LB via capacitors C11 and C12. The transmission control circuit A2 turns on or off the n-channel output MOS transistors M1, M2, M3 and M4 in accordance with a command signal input from an input terminal IN, so that differential signals are generated on the transmission lines LA and LB. A communication output terminal OUT_A, to which the connection of the source of the high-side output MOS transistor M1 and the drain of the low-side output MOS transistor M2 is connected, is connected to the transmission line LA via a capacitor C13. Likewise, a communication output terminal OUT_B, to which the connection of the source of the high-side output MOS transistor M3 and the drain of the low-side output MOS transistor M4 is connected, is connected to the transmission line LB via a capacitor C14.

For example, Japanese Laid-Open Patent Application No. 2002-319855 describes a technique related to a semiconductor integrated circuit capable of communicating with another semiconductor integrated circuit.

### SUMMARY OF THE INVENTION

According to an aspect of the present invention, a semiconductor integrated circuit includes an output MOS transistor including a first electrode connected to a power supply terminal and a second electrode connected to an output terminal, wherein the output MOS transistor is configured to turn on and off to cause communications to be performed with another semiconductor integrated circuit connected to the output terminal, and a back gate control circuit configured to control an electric potential at a back gate of the output MOS transistor so that a current path between the power supply terminal and the output terminal at a time when a power supply connected to the power supply terminal is turned off is interrupted.

The object and advantages of the invention will be realized and attained by means of the elements and combinations particularly pointed out in the claims.

It is to be understood that both the foregoing general description and the following detailed description are exemplary and explanatory and not restrictive of the invention.

### BRIEF DESCRIPTION OF THE DRAWINGS

Other objects, features and advantages of the present invention will become more apparent from the following detailed description when read in conjunction with the accompanying drawings, in which:

FIG. 1 is a diagram illustrating a configuration of a communication system according to related art;

FIG. 2 illustrates waveforms of differential signals at the time when a power supply is turned on and turned off according to related art;

FIG. 3 is a diagram illustrating a configuration of a semiconductor integrated circuit according to an embodiment;

FIG. 4 illustrates waveforms over the state transition of a power supply from ON state to OFF state according to an embodiment;

FIG. 5 is a diagram illustrating a configuration of a semiconductor integrated circuit according to an embodiment; and

FIG. 6 is a diagram illustrating a configuration of a semiconductor integrated circuit according to an embodiment.

### DETAILED DESCRIPTION OF THE PREFERRED EMBODIMENTS

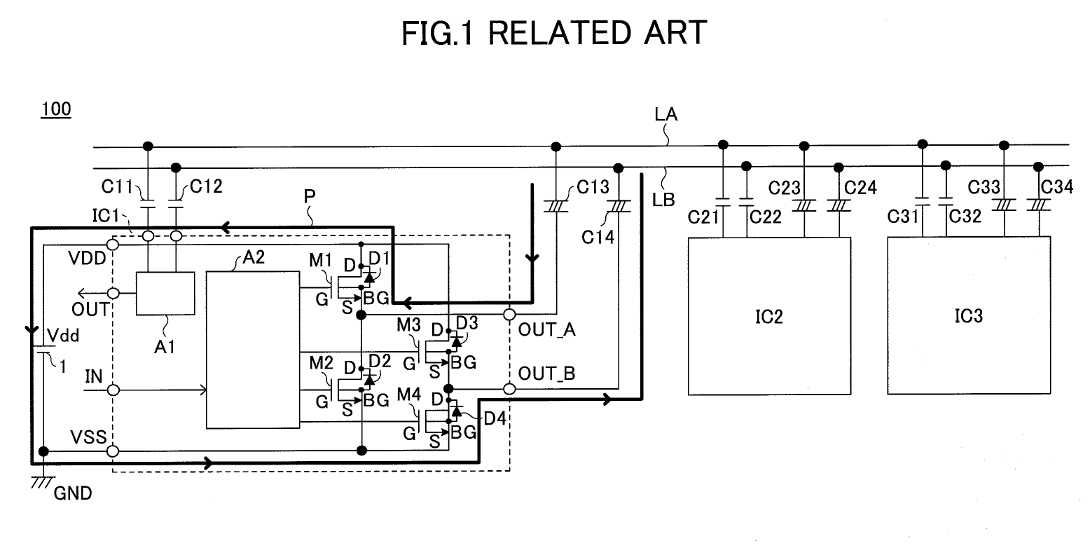

Referring to FIG. 1, a diode D1 exists as a parasitic element between the back gate and the drain of the output MOS transistor M1. Therefore, when the back gate and the source of the output MOS transistor M1 are connected, a current path P that goes through the diode D1 is generated when only the semiconductor integrated circuit IC1 is turned off (the supply voltage Vdd of a power supply 1 is 0 V) and the other semiconductor integrated circuits 102 and 103 are turned on. In the current path P, an electric current flows from the communication output terminal OUT_A to the diode D1 to a power supply terminal VDD to the power supply 1 to a power supply terminal VSS to a diode D4 to the communication output terminal OUT_B. The same is the case with a diode D3 of the output MOS transistor M3.

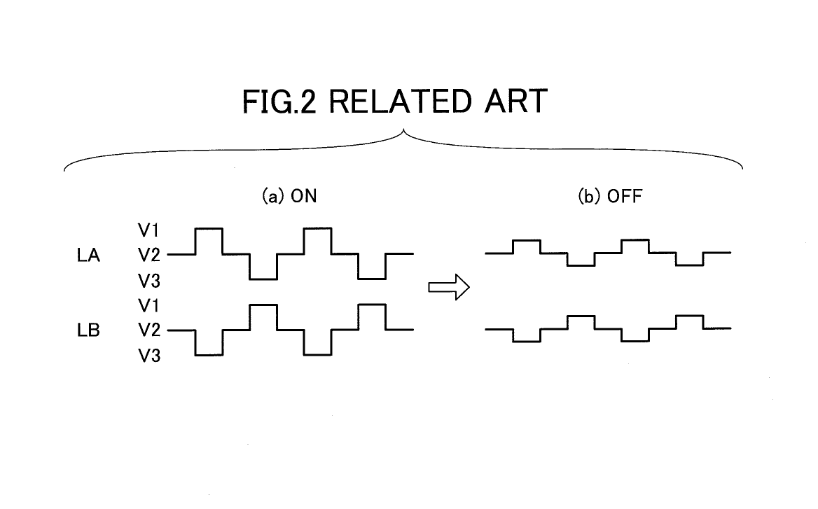

If this results in, for example, the loss of shape of the waveforms of differential signals on the transmission lines LA and LB to excessively reduce the difference in signal potential between the transmission lines LA and LB as illustrated in FIG. 2, the other semiconductor integrated circuit 102 or 103 may not properly transmit or receive the differential signals.

According to an aspect of the present invention, a semiconductor integrated circuit is provided that is capable of preventing other semiconductor integrated circuits from becoming unable to properly perform signal transmission or reception between them even when the semiconductor integrated circuit is turned off.

According to an aspect of the present invention, even when a semiconductor integrated circuit is turned off, it is possible to prevent other semiconductor integrated circuits from becoming unable to properly perform signal transmission or reception between them.

A description is given below, with reference to the accompanying drawings, of embodiments of the present invention.

In each of the MOS transistors illustrated in the drawings, G, D, S and BG represents a gate, a drain, a source and a back gate, respectively.

### First Embodiment

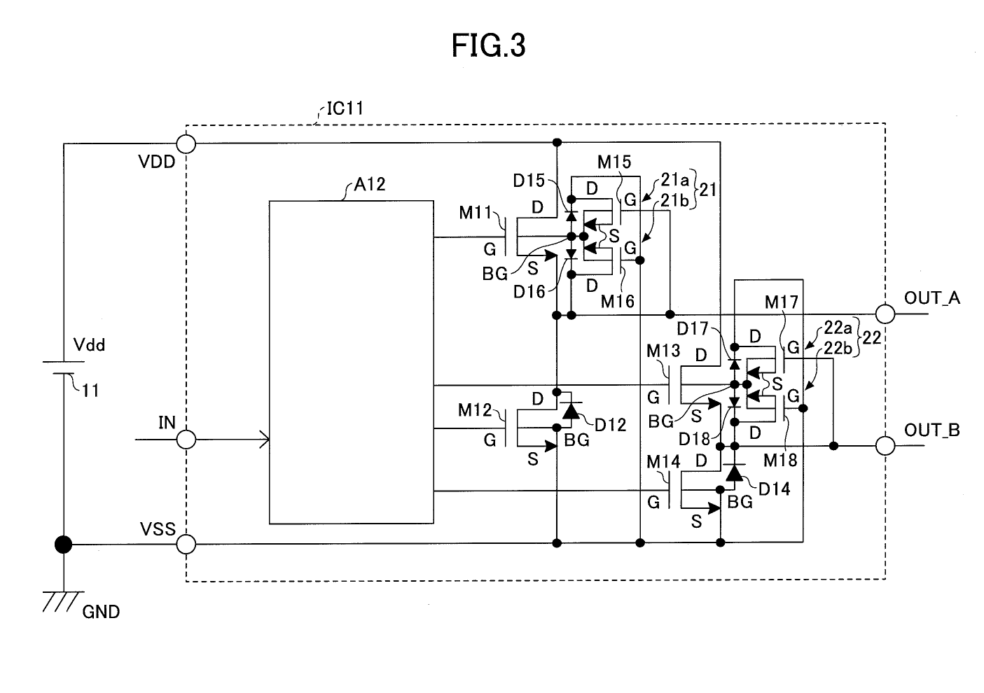

FIG. 3 is a diagram illustrating a configuration of a semiconductor integrated circuit IC11 according to a first embodiment. Like the semiconductor integrated circuit IC1 of the communication system 100 of FIG. 1, the semiconductor integrated circuit IC11 is housed in an electronic device, in which the semiconductor integrated circuit IC11 transmits and receives differential signals to and from other semiconductor integrated circuits, each having the same communication interface as the semiconductor integrated circuit IC11, via the transmission lines LA and LB (FIG. 1).

The semiconductor integrated circuit IC11 includes two power supply terminals VDD and VSS, and operates with supply voltage Vdd of a power supply 11, which is externally connected between the power supply terminals VDD and VSS. The power supply terminal VDD, to which the positive terminal of the power supply 11 is connected, is one of the two power supply terminals on a high potential side, and the power supply terminal VSS, to which the negative terminal of the power supply 11 is connected, is the other of the two power supply terminals on a low potential side. The negative terminal of the power supply 11 and the power supply terminal VSS are preferably connected to a predetermined fixed potential part (for example, connected to a ground potential part GND) in view of the stability of the electric potentials of the differential signals.

The semiconductor integrated circuit IC11 includes a transmission control circuit A12 and output MOS transistors M11, M12, M13 and M14. The transmission control circuit A12 turns on or off the n-channel output MOS transistors M11, M12, M13 and M14 in accordance with a command signal input from an input terminal IN, so that the differential signals are generated on the transmission lines LA and LB.

The output MOS transistor M11 includes a drain, which is a power-supply-side electrode connected to the power supply terminal VDD, a source, which is an output-side electrode connected to a communication output terminal OUT_A, and a gate, which is a control electrode connected to the transmission control circuit A12. The output MOS transistor M12 includes a source, which is a power-supply-side electrode connected to the power supply terminal VSS, a drain, which is an output-side electrode connected to the communication output terminal OUT_A, and a gate, which is a control electrode connected to the transmission control circuit A12. The output MOS transistor M13 includes a drain, which is a power-supply-side electrode connected to the power supply terminal VDD, a source, which is an output-side electrode connected to a communication output terminal OUT_B, and a gate, which is a control electrode connected to the transmission control circuit A12. The output MOS transistor M14 includes a source, which is a power-supply-side electrode connected to the power supply terminal VSS, a drain, which is an output-side electrode connected to the communication output terminal OUT_B, and a gate, which is a control electrode connected to the transmission control circuit A12.

The low-side output MOS transistors M12 and M14 includes respective diodes D12 and D14, each of which is a parasitic element between the back gate and the drain. Furthermore, the back gates of the low-side output MOS transistors M12 and M14 are directly connected to their respective sources.

On the other hand, the back gates of the high-side n-channel output MOS transistors M11 and M13 are connected to corresponding back gate control circuits formed on a p-type silicon substrate shared with the output MOS transistors M11 and M13. By way of example, FIG. 3 illustrates back gate control circuits 21 and 22 as such back gate control circuits.

The back gate control circuit 21 controls the electric potential at the back gate of the output MOS transistor M11, so that the current path between the power supply terminal VDD and the communication output terminal OUT_A is interrupted when the power supply 11 connected to the power supply terminal VDD is turned off. Likewise, the back gate control circuit 22 controls the electric potential at the back gate of the output MOS transistor M13, so that the current path between the power supply terminal VDD and the communication output terminal OUT_B is interrupted when the power supply 11 connected to the power supply terminal VDD is turned off. When the power supply 11 is turned off, the difference in electric potential between the power supply terminal VDD and the power supply terminal VSS is substantially 0 V. Accordingly, even when the power supply 11 of the semiconductor integrated circuit IC11 alone is turned off, the electric path between the power supply terminal VDD and the communication output terminal OUT_A and the electric path between the power supply terminal VDD and the communication output terminal OUT_B are interrupted by the back gate control circuits 21 and 22, respectively. Therefore, it is possible to prevent a sneak current that goes through a parasitic element formed between the back gate and the drain of each of the output MOS transistors M11 and M13. As a result, it is possible to prevent the loss of shape of the waveforms of the differential signals, so that it is possible to prevent other semiconductor integrated circuits from becoming unable to properly perform signal transmission or reception between them.

The back gate control circuit 21 includes, for example, two control circuits. By way of example, FIG. 3 illustrates a control circuit 21a as a first control circuit and illustrates a control circuit 21b as a second control circuit. Likewise, the back gate control circuit 22 includes, for example, two control circuits. By way of example, FIG. 3 illustrates a control circuit 22a as a first control circuit and illustrates a control circuit 22b as a second control circuit.

When the back gate of the output MOS transistor M11 and the power supply terminal VDD are short-circuited via the power supply terminal VSS and the power supply 11 by the control circuit 21a, the control circuit 21b interrupts a first current path (BG-OUT_A) between the back gate of the output MOS transistor M11 and the communication output terminal OUT_A. When the back gate of the output MOS transistor M11 and the communication output terminal OUT_A are short-circuited by the control circuit 21b, the control circuit 21a interrupts a second current path (BG-VDD #1) between the back gate of the output MOS transistor M11 and the power supply terminal VDD. The second current path (BG-VDD #1) at this time is a path that goes through the power supply terminal VSS and the power supply 11.

Irrespective of whether the power supply 11 is turned on or off, when one of the first current path (BG-OUT_A) and the second current path (BG-VDD #1) is short-circuited, the back gate control circuit 21 interrupts the other of the first current path (BG-OUT_A) and the second current path (BG-VDD #1). Accordingly, even when the back gate of the output MOS transistor M11 is short-circuited to the power supply terminal VDD via the power supply terminal VSS and the power supply 11 or is short-circuited to the communication output terminal OUT_A, it is possible to prevent a sneak current flowing between the power supply terminal VDD and the communication output terminal OUT_A via the back gate of the output MOS transistor M11.

When the back gate of the output MOS transistor M13 and the power supply terminal VDD are short-circuited via the power supply terminal VSS and the power supply 11 by the control circuit 22a, the control circuit 22b interrupts a third current path (BG-OUTB) between the back gate of the output MOS transistor M13 and the communication output terminal OUT_B. When the back gate of the output MOS transistor M13 and the communication output terminal OUT_B are short-circuited by the control circuit 22b, the control circuit 22a interrupts a fourth current path (BG-VDD #2) between the back gate of the output MOS transistor M13 and the power supply terminal VDD. The fourth current path (BG-VDD #2) at this time is a path that goes through the power supply terminal VSS and the power supply 11.

Irrespective of whether the power supply 11 is turned on or off, when one of the third current path (BG-OUT_B) and the fourth current path (BG-VDD #2) is short-circuited, the back gate control circuit 22 interrupts the other of the third current path (BG-OUT_B) and the fourth current path (BG-VDD #2). Accordingly, even when the back gate of the output MOS transistor M13 is short-circuited to the power supply terminal VDD via the power supply terminal VSS and the power supply 11 or is short-circuited to the communication output terminal OUT_B, it is possible to prevent a sneak current flowing between the power supply terminal VDD and the communication output terminal OUT_B via the back gate of the output MOS transistor M13.

Furthermore, “short-circuiting” may include short-circuiting with a resistance component (so-called “half short-circuiting”).

The control circuit 21a includes a first parasitic element that interrupts the second current path (BG-VDD #1) and a first control MOS transistor that forms the first parasitic element. By way of example, FIG. 3 illustrates a diode D15 as the first parasitic element and illustrates an n-channel control MOS transistor M15 as the first control MOS transistor.

The control MOS transistor M15 includes a drain connected to the power supply terminal VSS, a source and a back gate connected to the back gate of the output MOS transistor M11, and a gate connected to the communication output terminal OUT_A.

The diode D15 is a parasitic element formed between the p-type silicon substrate, to which the back gate of each of the output MOS transistor M11 and the control MOS transistor M15 is connected, and an n-well, to which the drain of the control MOS transistor M15 is connected. It is possible to interrupt an electric current flowing from the power supply terminal VDD to the back gate of the output MOT transistor M11 via the power supply 11 and the power supply terminal VSS with the diode D15, whose forward direction is from the back gate of the control MOS transistor M15 to the drain of the control MOS transistor M15.

The control circuit 21b includes a second parasitic element that interrupts the first current path (BG-OUT_A) and a second control MOS transistor that forms the second parasitic element. By way of example, FIG. 3 illustrates a diode D16 as the second parasitic element and illustrates an n-channel control MOS transistor M16 as the second control MOS transistor.

The control MOS transistor M16 includes a drain connected to the communication output terminal OUT_A, a source and a back gate connected to the back gate of the output MOS transistor M11, and a gate connected to the power supply terminal VSS.

The diode D16 is a parasitic element formed between the p-type silicon substrate, to which the back gate of each of the output MOS transistor M11 and the control MOS transistor M16 is connected, and an n-well, to which the drain of the control MOS transistor M16 is connected. It is possible to interrupt an electric current flowing from the communication output terminal OUT_A to the back gate of the output MOT transistor M11 with the diode D16, whose forward direction is from the back gate of the control MOS transistor M16 to the drain of the control MOS transistor M16.

The control circuit 22a includes a third parasitic element that interrupts the fourth current path (BG-VDD #2) and a third control MOS transistor that forms the third parasitic element. By way of example, FIG. 3 illustrates a diode D17 as the third parasitic element and illustrates an n-channel control MOS transistor M17 as the third control MOS transistor.

The control MOS transistor M17 includes a drain connected to the power supply terminal VSS, a source and a back gate connected to the back gate of the output MOS transistor M13, and a gate connected to the communication output terminal OUT_B.

The diode D17 is a parasitic element formed between the p-type silicon substrate, to which the back gate of each of the output MOS transistor M13 and the control MOS transistor M17 is connected, and an n-well, to which the drain of the control MOS transistor M17 is connected. It is possible to interrupt an electric current flowing from the power supply terminal VDD to the back gate of the output MOT transistor M13 via the power supply 11 and the power supply terminal VSS with the diode D17, whose forward direction is from the back gate of the control MOS transistor M17 to the drain of the control MOS transistor M17.

The control circuit 22b includes a fourth parasitic element that interrupts the third current path (BG-OUT_B) and a fourth control MOS transistor that faults the fourth parasitic element. By way of example, FIG. 3 illustrates a diode D18 as the fourth parasitic element and illustrates an n-channel control MOS transistor M18 as the fourth control MOS transistor.

The control MOS transistor M18 includes a drain connected to the communication output terminal OUT_B, a source and a back gate connected to the back gate of the output MOS transistor M13, and a gate connected to the power supply terminal VSS.

The diode D18 is a parasitic element formed between the p-type silicon substrate, to which the back gate of each of the output MOS transistor M13 and the control MOS transistor M18 is connected, and an n-well, to which the drain of the control MOS transistor M18 is connected. It is possible to interrupt an electric current flowing from the communication output terminal OUT_B to the back gate of the output MOT transistor M13 with the diode D18, whose forward direction is from the back gate of the control MOS transistor M18 to the drain of the control MOS transistor M18.

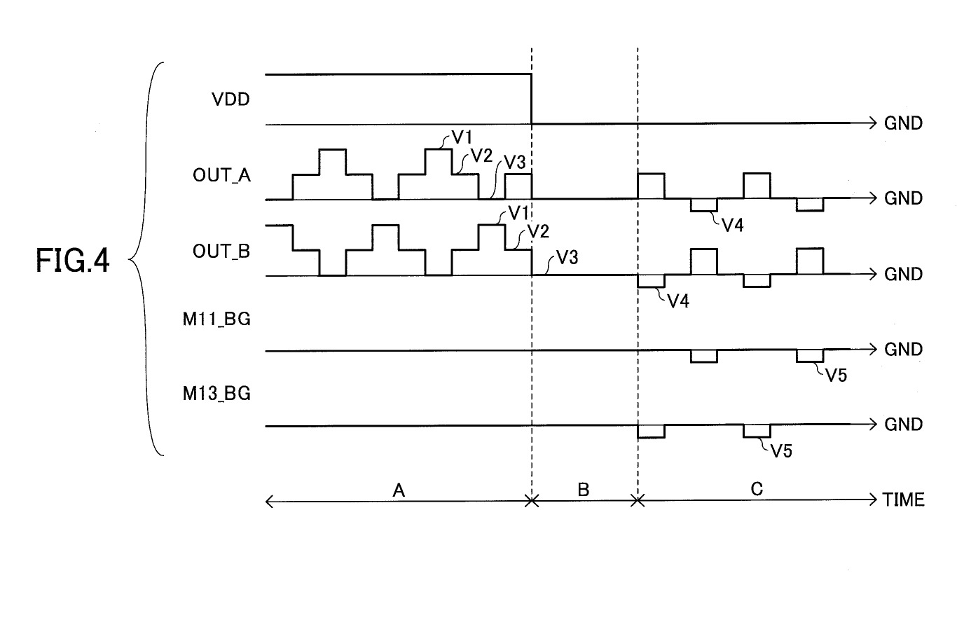

FIG. 4 illustrates waveforms at the power supply terminal VDD, the communication output terminal OUT_A, the communication output terminal OUT_B, the back gate of the output MOS transistor M11, and the back gate of the output MOS transistor M13 over the state transition of the power supply 11 from ON state to OFF state. In FIG. 4, A indicates a period in which the power supply 11 is turned on, B indicates a period in which the power supply 11 is turned off and no signals are input to or output from the communication output terminals OUT_A and OUT_B, and C indicates a period in which the power supply 11 is turned off and signals are input to or output from the communication output terminals OUT_A and OUT_B. Furthermore, regarding the waveforms at the communication output terminals OUT_A and OUT_B, V1 indicates a voltage at the time when the output MOS transistor M11 or M13 is turned on and the output MOS transistor M12 or M14 is turned off, V2 indicates a voltage at the time when both of the output MOS transistors M11 and M12 or M13 and M14 are turned off, and V3 indicates a voltage at the time when the output MOS transistor M11 or M13 is turned off and the output MOS transistor M12 or M14 is turned on.

When the power supply 11 is turned on (Period A in FIG. 4), the back gate of the output MOS transistor M11 is short-circuited to the power supply terminal VSS by the control MOS transistor M15 turning on. At this point, the control MOS transistor M16 is turned off. Therefore, the current path from the communication output terminal OUT_A to the power supply terminal VDD via the back gate and the drain of the output MOS transistor M11 is interrupted by the diode D16.

When the power supply 11 is turned on, the back gate of the output MOS transistor M11 is short-circuited to a predetermined fixed potential part such as a ground potential part GND via the power supply terminal VSS. Therefore, it is possible to reduce the effect of noise due to the switching of the output MOS transistors M11 and M12 over the back gate of the output MOS transistor M11.

When the power supply 11 is turned off and the electric potential at the communication output terminal OUT_A (for example, V2) is higher than or equal to the electric potential at the power supply terminal VSS (Period C in FIG. 4), the back gate of the output MOS transistor M11 is short-circuited to the power supply terminal VSS by the control MOS transistor M15 turning on.

At this point, the control MOS transistor M16 is turned off. Therefore, the current path from the communication output terminal OUT_A to the power supply terminal VDD via the back gate and the drain of the output MOS transistor M11 is interrupted by the diode D16.

When the power supply 11 is turned off and the electric potential at the communication output terminal OUT_A (V4) is lower than the electric potential at the power supply terminal VSS (Period C in FIG. 4), the back gate of the output MOS transistor M11 (V5) is short-circuited to the communication output terminal OUT_A by the control MOS transistor M16 turning on. At this point, the control MOS transistor M15 is turned off. Therefore, the current path from the power supply terminal VDD to the communication output terminal OUT_A via the power supply 11, the power supply terminal VSS, and the back gate and the source of the output MOS transistor M11 is interrupted by the diode D15.

The same applies to the case of the output MOS transistor M13 and the back gate control circuit 22, and accordingly, a description of this case is omitted.

### Second Embodiment

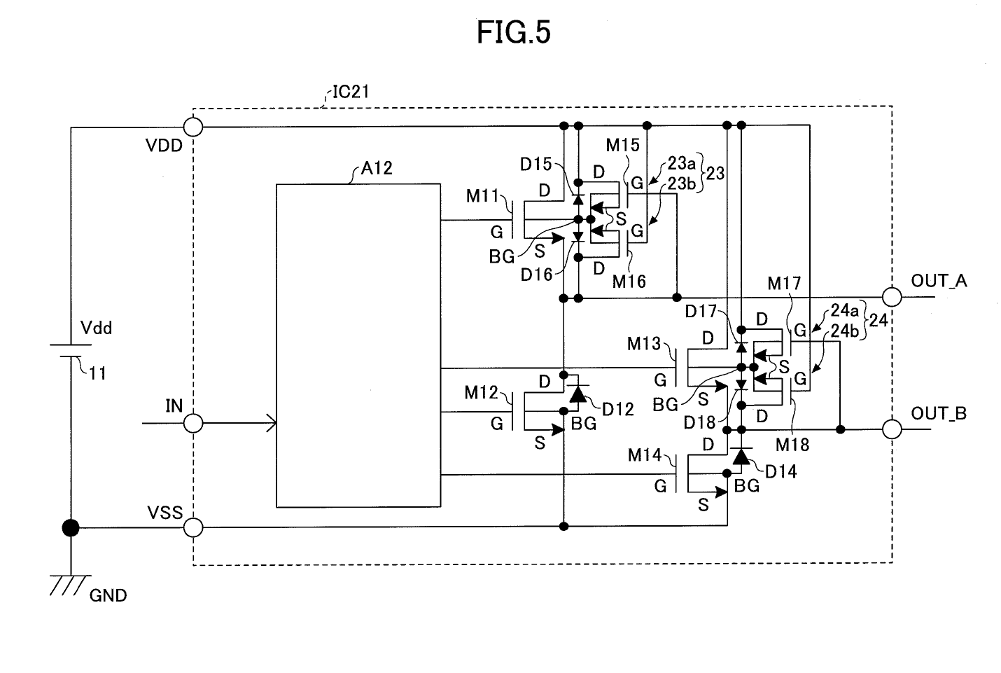

FIG. 5 is a diagram illustrating a configuration of a semiconductor integrated circuit IC21 according to a second embodiment. A description of the same configurations as those of the above-described embodiment is omitted or simplified. The control voltage of the back gate control circuit, which is a ground voltage at the power supply terminal VSS in the case of FIG. 3, may also be the supply voltage Vdd at the power supply terminal VDD as illustrated in FIG. 5.

A back gate control circuit 23 includes, for example, two control circuits. By way of example, FIG. 5 illustrates a control circuit 23a as a first control circuit and illustrates a control circuit 23b as a second control circuit. Likewise, a back gate control circuit 24 includes, for example, two control circuits. By way of example, FIG. 5 illustrates a control circuit 24a as a first control circuit and illustrates a control circuit 24b as a second control circuit.

When the back gate of the output MOS transistor M11 and the power supply terminal VDD are short-circuited by the control circuit 23a, the control circuit 23b interrupts a first current path (BG-OUT_A) between the back gate of the output MOS transistor M11 and the communication output teuninal OUT_A. When the back gate of the output MOS transistor M11 and the communication output terminal OUT_A are short-circuited by the control circuit 23b, the control circuit 23a interrupts a second current path (BG-VDD #1) between the back gate of the output MOS transistor M11 and the power supply terminal VDD.

Irrespective of whether the power supply 11 is turned on or off, when one of the first current path (BG-OUT_A) and the second current path (BG-VDD #1) is short-circuited, the back gate control circuit 23 interrupts the other of the first current path (BG-OUTA) and the second current path (BG-VDD #1). Accordingly, even when the back gate of the output MOS transistor M11 is short-circuited to the power supply terminal VDD or is short-circuited to the communication output terminal OUT_A, it is possible to prevent a sneak current flowing between the power supply terminal VDD and the communication output terminal OUT_A via the back gate of the output MOS transistor M11.

When the back gate of the output MOS transistor M13 and the power supply terminal VDD are short-circuited by the control circuit 24a, the control circuit 24b interrupts a third current path (BG-OUT_B) between the back gate of the output MOS transistor M13 and the communication output terminal OUT_B. When the back gate of the output MOS transistor M13 and the communication output terminal OUT_B are short-circuited by the control circuit 24b, the control circuit 24a interrupts a fourth current path (BG-VDD #2) between the back gate of the output MOS transistor M13 and the power supply terminal VDD.

Irrespective of whether the power supply 11 is turned on or off, when one of the third current path (BG-OUT_B) and the fourth current path (BG-VDD #2) is short-circuited, the back gate control circuit 24 interrupts the other of the third current path (BG-OUT_B) and the fourth current path (BG-VDD #2). Accordingly, even when the back gate of the output MOS transistor M13 is short-circuited to the power supply terminal VDD or is short-circuited to the communication output terminal OUT_B, it is possible to prevent a sneak current flowing between the power supply terminal VDD and the communication output terminal OUT_B via the back gate of the output MOS transistor M13.

Furthermore, “short-circuiting” may include short-circuiting with a resistance component (so-called “half short-circuiting”).

The control circuit 23a includes a first parasitic element that interrupts the second current path (BG-VDD #2) and a first control MOS transistor that forms the first parasitic element. By way of example, FIG. 5 illustrates the diode D15 as the first parasitic element and illustrates the n-channel control MOS transistor M15 as the first control MOS transistor.

The control MOS transistor M15 includes a drain connected to the power supply terminal VDD, a source and a back gate connected to the back gate of the output MOS transistor M11, and a gate connected to the communication output terminal OUT_A.

The diode D15 is a parasitic element formed between the p-type silicon substrate, to which the back gate of each of the output MOS transistor M11 and the control MOS transistor M15 is connected, and an n-well, to which the drain of the control MOS transistor M15 is connected. It is possible to interrupt an electric current flowing from the power supply terminal VDD to the back gate of the output MOT transistor M11 with the diode D15, whose forward direction is from the back gate of the control MOS transistor M15 to the drain of the control MOS transistor M15.

The control circuit 23b includes a second parasitic element that interrupts the first current path (BG-OUT_A) and a second control MOS transistor that forms the second parasitic element. By way of example, FIG. 5 illustrates the diode D16 as the second parasitic element and illustrates the n-channel control MOS transistor M16 as the second control MOS transistor.

The control MOS transistor M16 includes a drain connected to the communication output terminal OUT_A, a source and a back gate connected to the back gate of the output MOS transistor M11, and a gate connected to the power supply terminal VDD.

The diode D16 is a parasitic element formed between the p-type silicon substrate, to which the back gate of each of the output MOS transistor M11 and the control MOS transistor M16 is connected, and an n-well, to which the drain of the control MOS transistor M16 is connected. It is possible to interrupt an electric current flowing from the communication output terminal OUT_A to the back gate of the output MOT transistor M11 with the diode D16, whose forward direction is from the back gate of the control MOS transistor M16 to the drain of the control MOS transistor M16.

The same configuration applies to the control MOS transistors M17 and M18 and the output MOS transistor M13. Accordingly, a description of the configuration of the control MOS transistors M17 and M18 and the output MOS transistor M13 is omitted.

When the power supply 11 is turned on, the back gate of the output MOS transistor M11 is short-circuited to the communication output terminal OUT_A by the control MOS transistor M16 turning on. At this point, the control MOS transistor M15 is turned off. Therefore, the current path from the power supply terminal VDD to the communication output terminal OUT_A via the back gate and the source of the output MOS transistor M11 is interrupted by the diode D15.

When the power supply 11 is turned off, the back gate of the output MOS transistor M11 is short-circuited to the power supply terminal VDD by the control MOS transistor M15 turning on. At this point, the control MOS transistor M16 is turned off. Therefore, the current path from the communication output terminal OUT_A to the power supply terminal VDD via the back gate and the drain of the output MOS transistor M11 is interrupted by the diode D16.

The same applies to the case of the output MOS transistor M13 and the back gate control circuit 24. Accordingly, a description of this case is omitted.

### Third Embodiment

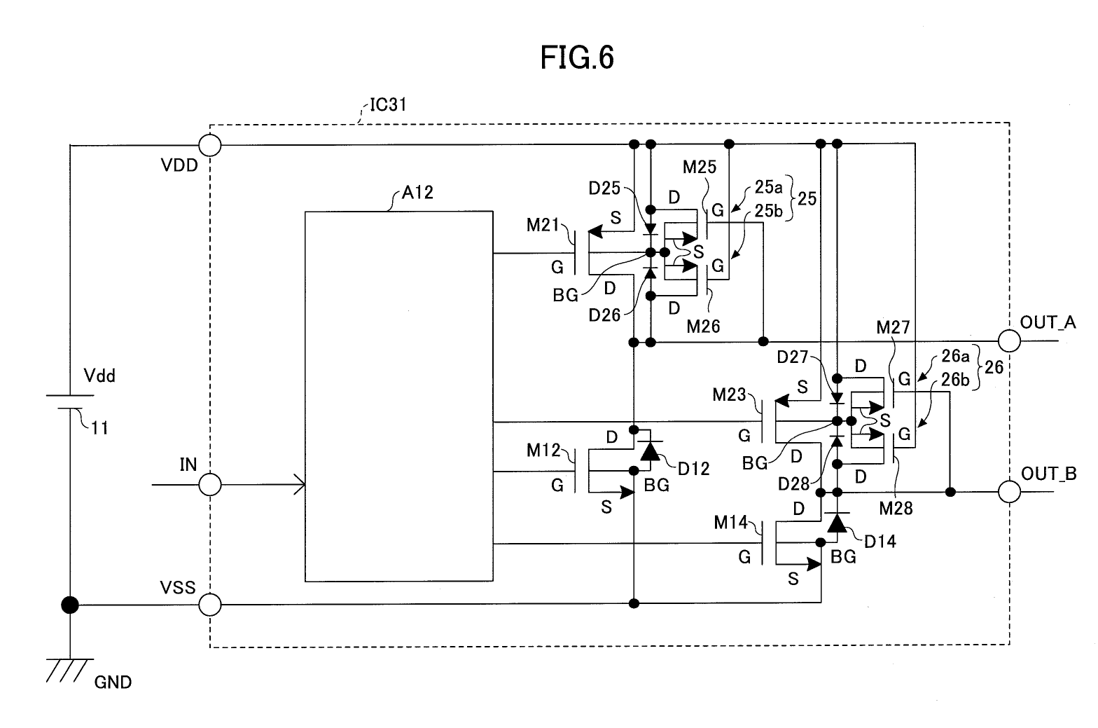

FIG. 6 is a diagram illustrating a configuration of a semiconductor integrated circuit 1031 according to a third embodiment. A description of the same configurations as those of the above-described embodiments is omitted or simplified. The conductivity type of the high-side output MOS transistor, which is an n-channel type in the case of FIG. 3, may also be a p-channel type as illustrated in FIG. 6.

An output MOS transistor M21 includes a drain, which is a power-supply-side electrode connected to the power supply terminal VDD, a source, which is an output-side electrode connected to the communication output terminal OUT_A, and a gate, which is a control electrode connected to the transmission control circuit A12. An output MOS transistor M23 includes a source, which is a power-supply-side electrode connected to the power supply terminal VDD, a drain, which is an output-side electrode connected to the communication output terminal OUT_B, and a gate, which is a control electrode connected to the transmission control circuit A12.

The back gates of the high-side p-channel output MOS transistors M21 and M23 are connected to corresponding back gate control circuits formed on an n-type silicon substrate shared with the output MOS transistors M21 and M23. By way of example, FIG. 6 illustrates back gate control circuits 25 and 26 as such back gate control circuits.

The back gate control circuit 25 includes, for example, two control circuits. By way of example, FIG. 6 illustrates a control circuit 25a as a first control circuit and illustrates a control circuit 25b as a second control circuit. Likewise, the back gate control circuit 26 includes, for example, two control circuits. By way of example, FIG. 6 illustrates a control circuit 26a as a first control circuit and illustrates a control circuit 26b as a second control circuit.

The control circuit 25a includes a first parasitic element that interrupts a second current path (BG-VDD #1) and a first control MOS transistor that forms the first parasitic element. By way of example, FIG. 6 illustrates a diode D25 as the first parasitic element and illustrates a p-channel control MOS transistor M25 as the first control MOS transistor.

The control MOS transistor M25 includes a drain connected to the power supply terminal VDD, a source and a back gate connected to the back gate of the output MOS transistor M21, and a gate connected to the communication output terminal OUT_A.

The diode D25 is a parasitic element formed between the n-type silicon substrate, to which the back gate of each of the output MOS transistor M21 and the control MOS transistor M25 is connected, and a p-well, to which the drain of the control MOS transistor M25 is connected. It is possible to interrupt an electric current flowing from the back gate of the output MOT transistor M21 to the power supply terminal VDD with the diode D25, whose forward direction is from the drain of the control MOS transistor M25 to the back gate of the control MOS transistor M25.

The control circuit 25b includes a second parasitic element that interrupts a first current path (BG-OUT_A) and a second control MOS transistor that forms the second parasitic element. By way of example, FIG. 6 illustrates a diode D26 as the second parasitic element and illustrates a p-channel control MOS transistor M26 as the second control MOS transistor.

The control MOS transistor M26 includes a drain connected to the communication output terminal OUT_A, a source and a back gate connected to the back gate of the output MOS transistor M21, and a gate connected to the power supply terminal VDD.

The diode D26 is a parasitic element formed between the n-type silicon substrate, to which the back gate of each of the output MOS transistor M21 and the control MOS transistor M26 is connected, and a p-well, to which the drain of the control MOS transistor M26 is connected. It is possible to interrupt an electric current flowing from the back gate of the output MOT transistor M21 to the communication output terminal OUT_A with the diode D26, whose forward direction is from the drain of the control MOS transistor M26 to the back gate of the control MOS transistor M26.

The control circuit 26a includes a third parasitic element that interrupts a fourth current path (BG-VDD #2) and a third control MOS transistor that forms the third parasitic element. By way of example, FIG. 6 illustrates a diode D27 as the third parasitic element and illustrates a p-channel control MOS transistor M27 as the third control MOS transistor.

The control MOS transistor M27 includes a drain connected to the power supply terminal VDD, a source and a back gate connected to the back gate of the output MOS transistor M23, and a gate connected to the communication output terminal OUT_B.

The diode D27 is a parasitic element formed between the n-type silicon substrate, to which the back gate of each of the output MOS transistor M23 and the control MOS transistor M27 is connected, and a p-well, to which the drain of the control MOS transistor M27 is connected. It is possible to interrupt an electric current flowing from the back gate of the output MOT transistor M23 to the power supply terminal VDD with the diode D27, whose forward direction is from the drain of the control MOS transistor M27 to the back gate of the control MOS transistor M27.

The control circuit 26b includes a fourth parasitic element that interrupts a third current path (BG-OUT_B) and a fourth control MOS transistor that forms the fourth parasitic element. By way of example, FIG. 6 illustrates a diode D28 as the second parasitic element and illustrates a p-channel control MOS transistor M28 as the fourth control MOS transistor.

The control MOS transistor M28 includes a drain connected to the communication output terminal OUT_B, a source and a back gate connected to the back gate of the output MOS transistor M23, and a gate connected to the power supply terminal VDD.

The diode D28 is a parasitic element formed between the n-type silicon substrate, to which the back gate of each of the output MOS transistor M23 and the control MOS transistor M28 is connected, and a p-well, to which the drain of the control MOS transistor M28 is connected. It is possible to interrupt an electric current flowing from the back gate of the output MOT transistor M23 to the communication output terminal OUT_B with the diode D28, whose forward direction is from the drain of the control MOS transistor M28 to the back gate of the control MOS transistor M28.

When the power supply 11 is turned on, the back gate of the output MOS transistor M21 is short-circuited to the power supply terminal VDD by the control MOS transistor M25 turning on. At this point, the control MOS transistor M26 is turned off. Therefore, the current path from the power supply terminal VDD to the communication output terminal OUT_A via the back gate and the source of the output MOS transistor M21 is interrupted by the diode D16.

When the power supply 11 is turned off, the back gate of the output MOS transistor M21 is short-circuited to the communication output terminal OUT_A by the control MOS transistor M26 turning on. At this point, the control MOS transistor M25 is turned off. Therefore, the current path from the communication output terminal OUT_A to the power supply terminal VDD via the back gate of the output MOS transistor M21 is interrupted by the diode D25.

The same applies to the case of the output MOS transistor M23 and the back gate control circuit 26. Accordingly, a description of this case is omitted.

A description is given above of semiconductor integrated circuits based on embodiments. All examples and conditional language provided herein are intended for pedagogical purposes of aiding the reader in understanding the invention and the concepts contributed by the inventors to further the art, and are not to be construed as limitations to such specifically recited examples and conditions, nor does the organization of such examples in the specification relate to a showing of the superiority or inferiority of the invention. Although one or more embodiments of the present invention have been described in detail, it should be understood that the various changes, substitutions, and alterations could be made hereto without departing from the spirit and scope of the invention.

For example, the signals transmitted and received by the semiconductor integrated circuit are not limited to differential signals, and may be signals of other communication formats, such as single-ended signals. Furthermore, the CMOS structure of a MOS transistor of the semiconductor integrated circuit may be a single-well, a twin-well or a triple-well structure.

What is claimed is:

1. A semiconductor integrated circuit, comprising:
an output MOS transistor including a first electrode connected to a power supply terminal and a second electrode connected to an output terminal, wherein the output MOS transistor is configured to turn on and off to cause communications to be performed with another semiconductor integrated circuit connected to the output terminal; and
a back gate control circuit configured to control an electric potential at a back gate of the output MOS transistor so that a current path between the power supply terminal and the output terminal at a time when a power supply connected to the power supply terminal is turned off is interrupted.

2. The semiconductor integrated circuit as claimed in claim 1, wherein
the back gate control circuit includes a first control circuit and a second control circuit,
the second control circuit is configured to interrupt a first current path between the back gate and the output terminal when the back gate and the power supply terminal are short-circuited by the first control circuit, and
the first control circuit is configured to interrupt a second current path between the back gate and the power supply terminal when the back gate and the output terminal are short-circuited by the second control circuit.

3. The semiconductor integrated circuit as claimed in claim 2, wherein
the first control circuit includes a first control MOS transistor that forms a first parasitic element configured to interrupt the second current path, and
the second control circuit includes a second control MOS transistor that forms a second parasitic element configured to interrupt the first current path.

4. The semiconductor integrated circuit as claimed in claim 2, wherein
the power supply terminal to which the first electrode is connected is a power supply terminal of the semiconductor integrated circuit on a high potential side, and
the first control circuit is configured to short-circuit the back gate and a power supply terminal of the semiconductor integrated circuit on a low potential side.

5. The semiconductor integrated circuit as claimed in claim 2, wherein
the power supply terminal to which the first electrode is connected is a power supply terminal of the semiconductor integrated circuit on a high potential side, and
the first control circuit is configured to short-circuit the back gate and the power supply terminal of the semiconductor integrated circuit on the high potential side.
